(19) United States
(12) Patent Application Publication
(10) Pub. No.: US 2006/0233289 A1
(43) Pub. Date: Oct. 19, 2006

(54) Mixed direct-indirect adaptation procedure applied to receiver filter

(75) Inventors: Daniel Massicotte, Trois-Rivieres (CA); Adel-Omar Dahmane, Trois-Rivierres (CA)

Correspondence Address: VENABLE LLP, P.O. BOX 34385, WASHINGTON, DC, 20045-9998, US

(73) Assignee: AXIOCOM INC., Trois-Rivieres, Quebec (CA)

(21) Appl. No.: 10/558,095

(22) PCT Filed: May 21, 2004
(86) PCT No.: PCT/CA04/00757

§ 371 Date: Nov. 23, 2005

(51) Int. Cl. H03D 1/04

(52) U.S. Cl. 375/346

(57) ABSTRACT

An adaptive procedure that optimizes the parameters of a receiver filter such as a Multiuser Detection (MUD) applied to Direct-Sequence Code Division Multiple Access (DS-CDMA) is disclosed. This procedure takes into account the constraints imposed by the absence of training data sequences sent by the transmitter and required to adapt the filter parameters at the receiver. The adaptation consists in using two distinct data sequences transmitted through the same channel; one data sequence is transmitted as payload data and a second data sequence is transmitted as training data used to adapt the filter parameters at the receiver. Parameters of the receiver filter are adapted in presence of varying channels at the same time as the data information sequences are transmitted. The adaptation is realized following a mixed adaptation procedure based on a direct (without channel identification) and indirect (with channel identification) scheme. The invention is described for UMTS (Universal Mobile Telecommunications System) application in cellular communications system.

### TECHNICAL FIELD

This invention pertains to the field of digital telecommunications. More precisely, this invention relates to a mixed direct-indirect adaptation procedure applied to receiver filter.

### BACKGROUND OF THE INVENTION

Channel equalization is one of the fundamental problems in digital telecommunications. FIG. 1 shows a model of a typical communication system incorporating the equalization/detection techniques.

Unlike TDMA (Time Division Multiple Access) equalizers, the DS-CDMA equalizers consist in removing the InterSymbol Interference (ISI) from the data received through a telecommunications channel and the Multiple Access Interference (MAI).

Referring to FIG. 2a, there is shown a model of a DS-CDMA baseband system (M. Latva-aho and M. J. Juntti, “LMMSE Detection for DS-CDMA Systems in Fading Channels”, IEEE Transactions on Communications, Vol. 48, No. 2, 2000, pp 194-199 and M. J. Juntti, and M. Latva-Aho, “Multiuser Receivers for CDMA Systems in Rayleigh Fading Channels”, IEEE Transactions on Vehicular Technology, Vol. 49, No. 3, May 2000, pp. 885-899 and A. O. Dahmane and D. Massicotte, “Nonlinear Multiuser Receiver for UMTS Communications”, IEEE-Semiannual Vehicular Technology Conference, Vancouver, 24-29 Sept. 2002, pp. 252-256.). In the model, K users are transmitting symbols from the alphabet Ξ={−1,1}. Each user's symbol is spread by its respective code sequence of length N_{c} and denoted by sₖ. The code sequence is generated by combining OVSF codes with short scrambling codes (Verdù S., Multiuser Detection, Cambridge University Press, 1998). The symbol period is denoted by T and the chip period is denoted by T_{c} where N_{c}=T/T_{c} is an integer.

All users are assumed to use the same chip pulse shaping filter 230, denoted by ψ(t) which is in this case the square root raised cosine with roll off factor β=0.22. Each user k is transmitting its data through a Rayleigh fading channel 240 of Lₖ paths denoted by hₖ(t), with maximum delay spread of τₘ. Baud spaced indexes are represented by n, chip spaced indexes are represented by m and user k's n^{th} transmit symbol is bₖ⁽ⁿ⁾ unless otherwise stated. The model used is in Baud spaced form on but can be easily extended to fractionally spaced form.

The k^{th} user's continuous time spreading waveform is

$${s}_{k}^{( n )} ( t ) = {\sum }_{m = 0}^{{N}_{c} - 1} {s}_{k , m}^{( n )} ψ ( t - {mT}_{c} ) . \qquad ( Equation 1 )$$

The baseband received signal of all users is

$$r ( t ) = {\sum }_{k = 1}^{k} ( {\sum }_{n = 0}^{{N}_{b} - 1} ( ( {A}_{k} {b}_{k}^{( n )} {s}_{k}^{( n )} ( t - nT ) + j {β}_{ k} {P}_{ k}^{ train ( n )} {p}_{ k}^{( n )} ( t ) ) * {h}_{ k}^{( n )} ( t ) ) ) + η ( t ) \qquad ( Equation 2 )$$

and is outputted by adding unit 260.

In Equation 2, N_{b} represents the number of received symbols, Aₖ represents the received amplitude of user k, η(t) represents the additive Gaussian noise with variance σ_{η}², * represents linear convolution, pₖ⁽ⁿ⁾(t) is the periodic control (pilot) waveform of the k^{th} user overlapping the n^{th} traffic bit bₖ⁽ⁿ⁾ and having the same short scrambling code as the traffic data with all ones (3GPP−TS 25.213 v4.1.0 (2001-06): Spreading and Modulation (FDD)) as shown in FIG. 2b and j=\sqrt{−1}.

The transmission channel hₖ⁽ⁿ⁾(t) for user k of the Rayleigh fading channel 240 is defined by

$${h}_{k}^{( n )} ( t ) = {\sum }_{l = 1}^{{L}_{k}} {h}_{k , l}^{( n )} δ ( t - {τ}_{k , l} ) \qquad ( Equation 3 )$$

where Lₖ is the number of propagation paths, h_{k,l}⁽ⁿ⁾ the complex gain of the path l for user k at time n, τ_{k,l} is the propagation delay and δ(t) is the Dirac pulse.

The received signal may then be written as follows \tilde{r}(t)=H(b(t),p(t))+η(t) (Equation 4) where H(●) represents the channel-model 270, first part of the Equation (2).

The discrete form of the last equation, in Baud spaced, is \tilde{r}=H(b,p)+η (Equation 5), where \tilde{r}=[\tilde{r}⁽⁰⁾^{^{T}}, . . . , \tilde{r}^{(N}^{_{b}}⁻¹ ^{^{T}}]^{T} and \tilde{r}⁽ⁿ⁾=[\tilde{r}(T_{c}(nN_{c}+1)), . . . , \tilde{r}(T_{C}(n+1)N_{C})]^{T} (Equation 6), the transmitted symbols are b=[b⁽⁰⁾^{^{T}}, . . . , b^{(N}^{_{b}}⁻¹⁾^{^{T}}]^{T} and b⁽ⁿ⁾=[b₁⁽ⁿ⁾, . . . , b_{K}⁽ⁿ⁾]^{T} (Equation 7) and transmitted control (pilots) are p=[p^{(0)T}, . . . , p^{(Np-1)T}]^{T} and p⁽ⁿ⁾=[p₁⁽ⁿ⁾, . . . , p_{K}⁽ⁿ⁾]^{T} (Equation 8).

### SUMMARY OF THE INVENTION

It is an object of the invention to provide an apparatus for providing a regenerated data sequence.

Yet another object of the invention is to provide a regenerated data sequence.

It is another object of the invention to provide an apparatus for providing a regenerated control sequence.

It is another object of the invention to provide an apparatus for providing a regenerated data sequence.

According to an aspect of the invention, there is provided an apparatus for providing a regenerated data sequence, the apparatus comprising a channel identification unit receiving, from a communication channel, a transmitted signal (\tilde{r}) and a training control sequence (p^{train}) to provide a plurality of channel coefficients representative of the communication channel (\hat{h₁} . . . \hat{hₖ}) and a channel modeling unit filtering the plurality of channel coefficients representative of the communication channel (\hat{h₁} . . . \hat{hₖ}) with a known training data sequence (X) to provide the regenerated data sequence (Y).

According to an aspect of the invention, there is provided a method for providing a regenerated data sequence, the method comprising: receiving, from a communication channel, a transmitted signal (\tilde{r}) and a training control sequence (p^{train}) to provide a plurality of channel coefficients representative of the communication channel (\hat{h₁} . . . \hat{hₖ}) and filtering the plurality of channel coefficients representative of the communication channel (\hat{h₁} . . . \hat{hₖ}) with a known training data sequence (X) to provide the regenerated data sequence (Y).

A embodiment of an adaptation procedure that optimizes the parameters of a receiver filters such as a Multiuser Detection (MUD) applied to Direct-Sequence Code Division Multiple Access (DS-CDMA) is disclosed. This procedure takes into account the constraints imposed by the absence of training data sequences sent by the transmitter and required to adapt the filter parameters at the receiver.

The adaptation consists in using two distinct data sequences transmitted through the same channel; one data sequence is transmitted as payload data and a second data sequence is transmitted as training data used to adapt the filter parameters at the receiver. Parameters of the receiver filter are adapted in presence of varying channels at the same time as the data information sequences are transmitted. The adaptation is realized following a mixed adaptation procedure based on a direct (without channel identification) and indirect, (with channel identification) scheme. The invention is described for UMTS (Universal Mobile Telecommunications System) application in cellular communications system.

### BRIEF DESCRIPTION OF THE DRAWINGS

Further features and advantages of the present invention will become apparent from the following detailed description, taken in combination with the appended drawings, in which:

FIG. 1 is a block diagram showing a model of a typical communication system;

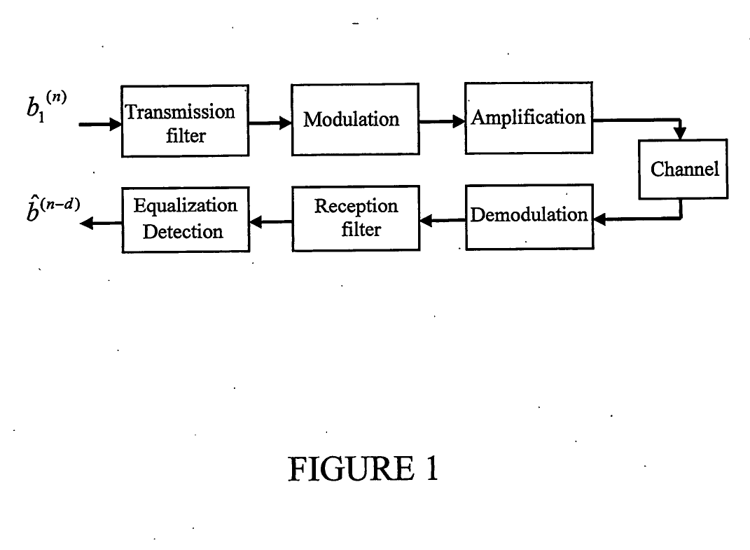

FIG. 2a is a block diagram showing a prior art baseband model of the DS-CDMA system;

FIG. 2b is a block diagram showing, inter alia, traffic data and a pilot;

FIG. 3 is a block diagram showing a data sequence generator apparatus comprising a channel identification unit and a channel modeling unit in accordance with one embodiment of the invention;

FIG. 4 is a block diagram showing a direct adaptation method filters receiver structure with Pilot Free for DS-CDMA systems in accordance with one embodiment of the invention;

FIG. 5 is a block diagram showing an indirect adaptation method filters receiver structure with Pilot Free for DS-CDMA systems in accordance with one embodiment of the invention;

FIG. 6 is a block diagram showing a mixed method cascade filters receiver structure for DS-CDMA systems in accordance with one embodiment of the invention;

FIG. 7 is a block diagram showing a mixed method cascade filters receiver structure with Pilot Free for DS-CDMA systems in accordance with one embodiment of the invention and

FIG. 8 is a block diagram showing a training data sequence generator apparatus at the receiver in accordance with one embodiment of the invention.

### DETAILED DESCRIPTION OF THE PREFERRED EMBODIMENT

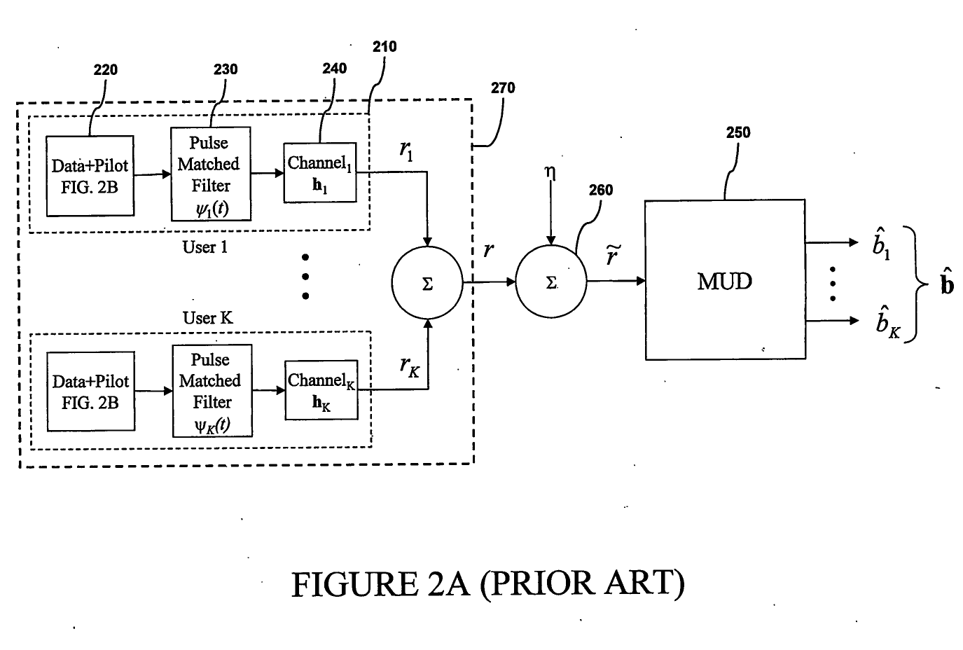

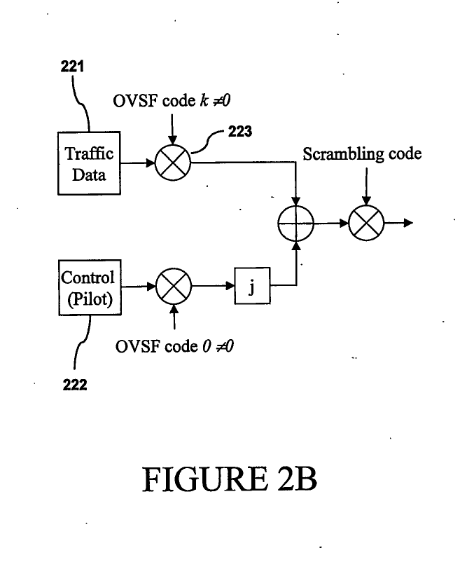

Various algorithms have been developed in order to solve the problem of obtaining the estimate transmit data \hat{b}ₖ⁽ⁿ⁾ of the original sequence bₖ⁽ⁿ⁾ on the basis of \tilde{r}^{(m)}. Most of the algorithms may be reduced to digital filtering of the sequence of symbols corrupted by the intersymbol interferences and the Multiple Access Interferences \hat{b}ₖ⁽ⁿ⁾=F[\tilde{r}⁽ⁿ⁾] (Equation 9) where F[●] represents the MUD filter 250 of FIG. 2a.

Still referring to FIG. 2a, in order to have a discrete linear model, a MUD filter 250 of N_{f} dimension to which will be applied the output of the channel model has to be considered. The vector \tilde{r}⁽ⁿ⁾=[\tilde{r}^{(m)}, \tilde{r}^{(m-1)}, . . . , \tilde{r}^{(m-N}^{_{f}}⁺¹⁾]^{T} (Equation 10) is introduced.

The first receiver, proposed for IS-95, was the Rake receiver to take advantage of the fading nature of the channel. However, the near-far problem made the receiver inefficient (Nolma H., et Toskala A., WCDMA for UMTS: Radio Access For Third Generation Mobile Communications, John Wiley & Sons LTD, 2000).

Linear and non-linear MUD filters 250 (F[●]) have been proposed in order to overcome the near-far problem. The first were considered mostly to extend the use of TDMA equalizers to DS-CDMA ones. The algorithms are Maximum Likelihood Sequence Estimation (MLSE) for sequence detection and Maximum a-posteriori (MAP) for symbol-by-symbol detection. Unfortunately, the algorithms are unpractical since the complexity grows exponentially with the number of users (Verdu S., Multiuser Detection, Cambridge University Press, 1998). Other algorithms widely proposed are the ZF (Zero Forcing) and MMSE (Minimum Mean Square Error) which need the exact impulse response of all the users' channels (Klein S., Kaleh G. K., et Baier P. W., “Zero Forcing and Minimum Mean-Square-Error Equalization for Multiuser Detection in Code-Division Multiple-Access Channels”, IEEE Transactions on Vehicular Technology, Vol. 45, No. 2, Mai 1996, pp. 276-287). This is unpractical. Even the adaptive version of the Minimum Mean Square Error algorithm is too complex to be adopted in real life applications. PIC (Parallel Interference Cancellation) algorithms and SIC (Successive Interference Cancellation) algorithms have also been previously disclosed. The optimal version of these two receivers needs the knowledge of the amplitudes of all the received users free of the multiple access interferences. This is difficult to obtain since the hard thing to do is to remove the multiple access interferences.

Other receivers were proposed based on linear filters and neural networks without the achievement of one general structure to equalize all the users (Das K., et Morgera S. D., “Adaptive Interference Cancellation for DS-CDMA Systems Using Neural Network Techniques”, IEEE Journal on Selected Areas in Communications, Vol. 16, No. 9, 1998, pp. 1774-1784.).

A MUD filter will be considered linear if a function F[●] of the equation (9) is linear in its arguments in any other case it will be treated as a non-linear one. For instance, MUD filters based on neural networks are considered to be non-linear.

A MUD filter is supervised if it is necessary to send a known sequence, referred to as a Training sequence generator, in order to estimate its coefficients (b^{train} and p^{train} for the transmit data and control (pilot) respectively).

For time-varying channels, it results in loss of available bandwidth and the adaptation can use decision directed techniques corresponding to a first avenue to the Blind method. In contrast with supervised MUD filters, blind MUD filters estimate its coefficients without knowledge of the sent training sequence thus increasing the bandwidth efficiency.

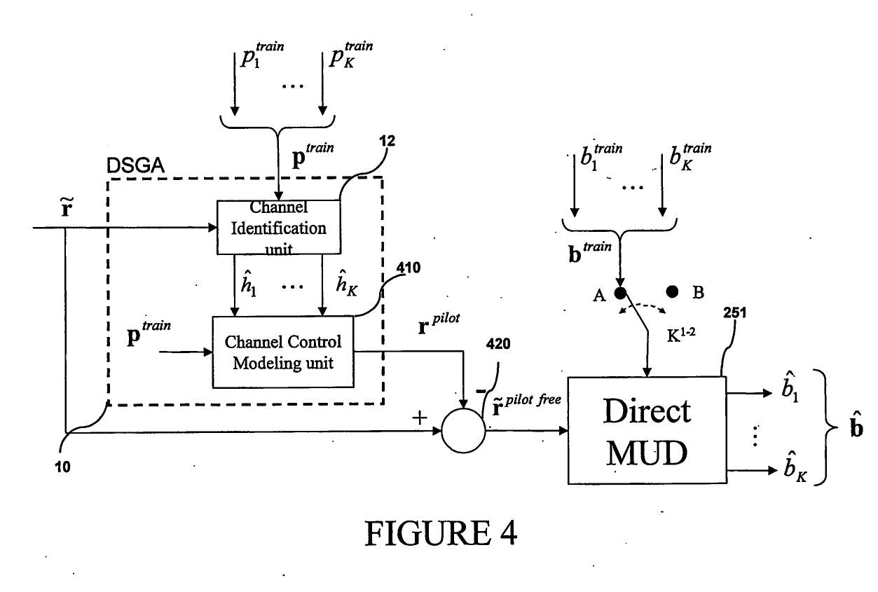

A MUD filter has control component if the receive signal \tilde{r} is send directly at the MUD filter input, as shown for instance in FIGS. 4, 6 and 7.

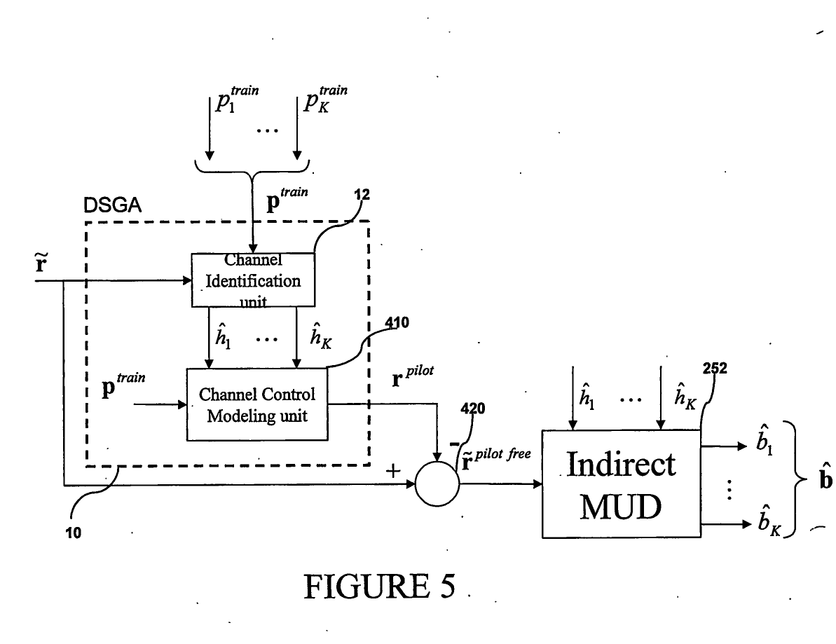

Otherwise, a MUD filter is control (pilot) free if the signal is removed from the receive signal \tilde{r} and after applied at the MUD filter input, as shown for instance in FIGS. 4 and 5.

The MUD filter 250 is based on two known approaches.

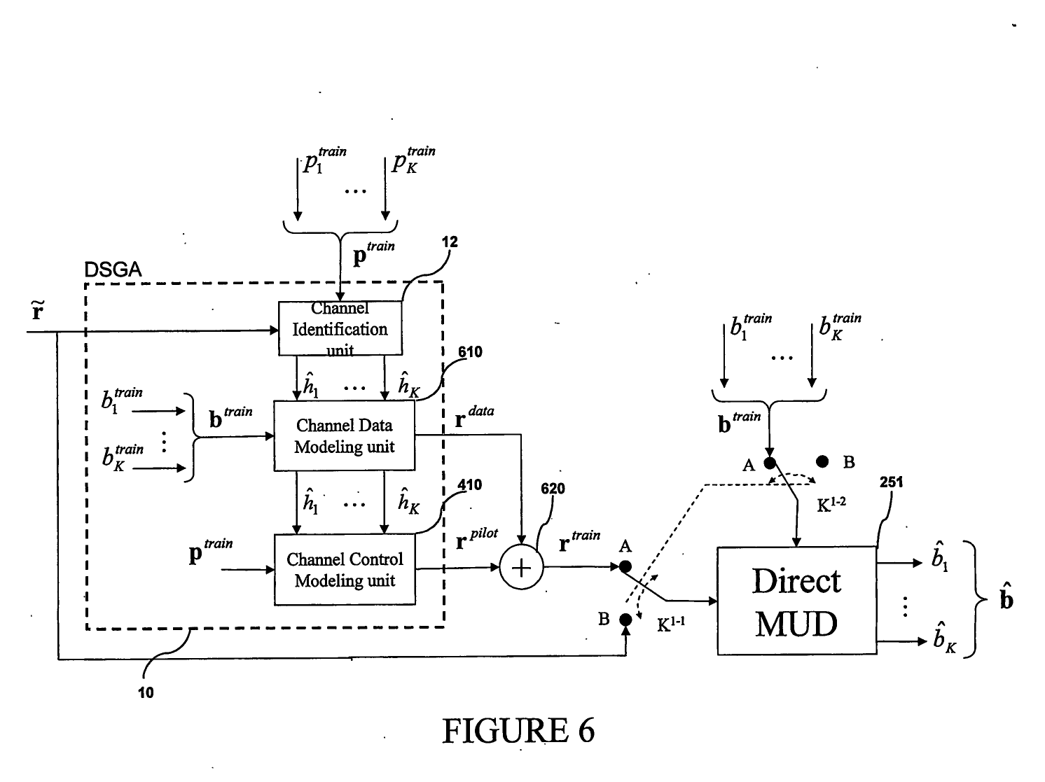

A MUD filter is direct such as the MUD filter 251, shown in FIG. 6, if its coefficients are obtained from the available data.

The MUD filter is indirect, as the MUD filter 252, shown in FIG. 5, if its coefficients are calculated on the basis of previously identified parameters (taps ĥₖ and delays \hat{τ}ₖ) of the channel H[●] 270 by using a channel identification unit 12 such as the Correlator (Bhashyam, S., Aazhang, B., “Multiuser channel estimation and tracking for long-code CDMA systems”, IEEE Transactions on communications, Volume: 50 , Issue: 7 , July 2002, pp. 1081-1090.).

In practice the indirect approach is usually used if the channel model is linear since channel identification unit 12 is therefore simple to implement.

As discussed below two or more distinct data sequences, transmitted through a same channel may be used.

A first data sequence b is transmitted as payload data sequence.

A second data sequence p^{train} is transmitted as training control (pilot) sequence used in order to identify the parameters of the channel at the receiver using a channel identification method.

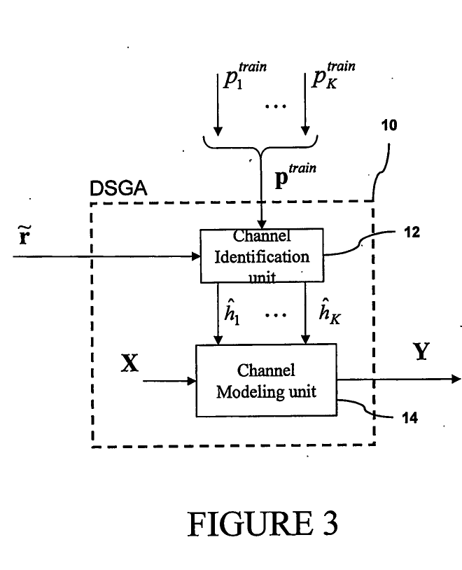

Now referring to FIG. 3, there is shown an example of a data sequence generator 10 according to one embodiment of the invention.

The data sequence generator 10 comprises a channel identification unit 12 and a channel modeling unit 14.

The channel identification unit 12 receives a transmitted signal \tilde{r} and a training control sequence p^{train}, performs a channel identification in order to provide a plurality of channel coefficients representative of the communication channel ĥ₁ . . . ĥₖ.

The channel modeling unit 14 receives the plurality of channel coefficients representative of the communication channel ĥ₁ . . . ĥₖ and a known training data sequence (X) and filters the plurality of channel coefficients representative of the communication channel ĥ₁ . . . ĥₖ with the known training data sequence (X) in order to provide a regenerated data sequence (Y).

It will be appreciated that in one embodiment the known training data sequence (X) may be the training control sequence p^{train} (see FIG. 4). In such case the channel modeling unit 14 comprises a channel control modeling unit 410 and the regenerated data sequence (Y) comprises a regenerated control sequence r^{pilot}. An example incorporating such embodiment will be described further below.

In another embodiment, the known training data sequence (X) may be the training data sequence b^{train} (see FIG. 6). In such case the channel modeling unit 14 comprises a channel data modeling 610 and the regenerated data sequence (Y) comprises a regenerated training sequence r^{train}. An example incorporating such embodiment will be described further below.

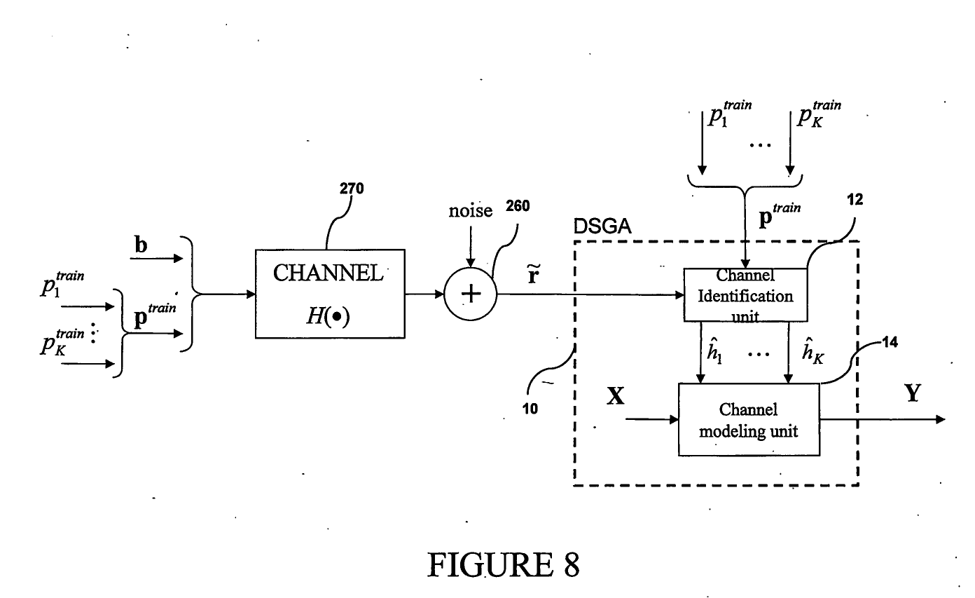

Now referring to FIG. 8, there is shown an example where the data sequence generator 10 (DSGA) is located at a receiver 80.

The training control (pilot) sequence p^{train} is transmitted through the channel H[●] 270 in order to perform the training sequence of the channel identification unit 12 for all channels defined by the K users.

The training control (pilot) sequence p^{train}, known by the receiver, is used to identify the parameters of the channel model H(●).

A channel identification method such as the correlator, maximum likelihood, etc. and/or following an adaptation algorithm such as the LMS, RLS, Kalman filter, Backpropagation Neural Network, etc . . . is performed by the channel identification unit 12.

When the plurality of channel coefficients representative of the communication channel ĥ₁ . . . ĥₖ are identified by the channel identification unit 12, the plurality of channel coefficients representative of the communication channel ĥ₁ . . . ĥₖ are sent to the channel modeling unit 14.

A set of training data sequences (X) is generated locally at the receiver. The set of training data sequences (X) is used in order to generate the regenerated data sequence (Y) using the channel modeling unit 14. The set of training data sequences (X) is used at the receiver in order to adapt the receiver filters.

The channel modeling unit 10 may be defined by

$${r}^{Data} ( t ) = {\sum }_{k = 1}^{K} ( {\sum }_{n = 0}^{{N}_{b} - 1} ( ( {b}_{k}^{train ( n )} {s}_{k}^{( n )} ( t - nT ) ) * {\hat{h}}_{k}^{( n )} ( t ) ) ) \qquad ( Equation 11 )$$

in the case where Y=r^{data} and X=b^{train}.

Alternatively, the channel modeling unit 10 may be defined by

$${r}^{pilot} ( t ) = {\sum }_{k = 0}^{K} ( {\sum }_{n = 0}^{{N}_{b} - 1} ( ( {jP}_{k}^{train ( n )} {p}_{k}^{( n )} ( t - nT ) ) * {\hat{h}}_{k}^{( n )} ( t ) ) ) \qquad ( Equation 12 )$$

in the case where X=b^{train} and Y=r^{pilot}.

In the case of a MUD filter adaptation receiver, the MUD filter is designed in a mixed manner where coefficients are obtained on the basis of indirect, and direct methods as shown in FIGS. 5 and 6.

Now referring to FIG. 4, there is shown a receiver operating according to a direct adaptation method with a control (pilot) cancellation.

More precisely, the receiver comprises a channel modeling unit 10 having a channel identification unit 12 and a channel control modeling unit 410.

The receiver further comprises a control signal cancellation unit 420, a direct MUD filter 251 and a switch K¹⁻².

The control (pilot) cancellation and the adaptation of the direct MUD filter parameters are made simultaneously by applying both the direct and indirect processes.

According to a first step, the parameters of the direct MUD filter 251 and of the channel identification unit 12 are initialized.

According to a second step, the training control sequence p^{train} is transmitted through the channel in order to obtain the training sequence of the channel identification unit 12 for all channels defined by the K users. Concurrently, the training data sequence b^{train} and/or payload data sequence b, not shown, containing the information sent by all users are transmitted. The training data sequence p^{train} is known by the receiver and the training data sequence ^{train} is used to identify the parameters of the channel model H(●). A channel identification algorithm such as the Correlator, Maximum Likelihood, etc. and/or following an adaptation algorithm such as the LMS, RLS, Kalman filter, Backpropagation Neural Network, etc. is used by the channel identification unit 12 in order to determine the plurality of channel coefficients representative of the communication channel ĥ₁ . . . ĥₖ.

According to a third step, when the plurality of channel coefficients representative of the communication channel ĥ₁ . . . ĥₖ are identified, the regenerated control sequence r^{pilot} at the receiver is generated using the channel control modeling unit 410 and the training control sequence p^{train}.

According to a fourth step, the effect of the pilot data interfere with the training data or payload data and must be cancelled. The cancellation is realized by a subtraction of the received data \tilde{r} by the regenerated control sequence r^{pilot} using the control signal cancellation unit 420. The new received data, \tilde{r}^{pilot free} are provided by the control signal cancellation unit 420.

Concurrently to the second step, the switch K¹⁻² is in position A in order to transmit the training data sequence b^{train} which is needed in order to perform the training sequence for all channels defined by the K users.

According to a sixth step, the data \tilde{r}^{pilot free} and the training data sequence b^{train} which are known by the receiver are used in order to adapt the parameters of the direct MUD filter 251 following an adaptation algorithm such as an LMS, RLS, Backpropagation Neural Network, etc.

According to a seventh step, when the parameters of the direct MUD filter 251 are adapted, the switch K¹⁻² is in position B. The payload data b containing the information are estimated with the direct MUD filter 251 using the data \tilde{e}^{pilot free}. In the B position, no training data are transmitted and the direct MUD filter 251 parameters are unchanged.

Concurrently to the seventh step, the channel parameters are tracked using the second step and the received data with pilot free are computed by applying the third and the fourth step.

Periodically, the switch K¹⁻² is changed alternatively between positions A and B to adapt the parameters of the direct MUD filter 251 in variant channel H(●) conditions.

Now referring to FIG. 5, there is shown receiver operating according to an indirect adaptation method comprising a control (pilot) cancellation. The pilot cancellation is described by the following steps.

According to a first step, the parameters of the channel identification unit 12 are initialized.

According to a second step, the training control sequence p^{train} is transmitted in order to perform the training sequence of the channel identification for all channels defined by the K users. Concurrently, the payload data b, not shown, sent by all users are transmitted. The training control sequence p^{train} are known by the receiver and they are used to identify the parameters of the channel model H(●). The channel identification unit 12 using a method such as the Correlator, Maximum Likelihood, etc. and/or following an adaptation algorithm such as the LMS, RLS, Kalman filter, Backpropagation Neural Network, etc. are used in order to determine the plurality of channel coefficients representative of the communication channel ĥ₁ . . . ĥₖ.

According to a third step, when the plurality of channel coefficients representative of the communication channel ĥ₁ . . . ĥₖ are identified, the pilot data at the receiver r^{pilot} are generated using the channel control modeling unit 410 and the training control sequence p^{train}.

According to a fourth step, in pilot free conditions, the effect of the control (pilot) data interferes with the payload data and must therefore be cancelled. The cancellation is realized by a subtraction of the received data \tilde{r} by the regenerated control sequence r^{pilot} using the control signal cancellation unit 420. The control signal cancellation unit 420 provides \tilde{r}^{pilot free}.

Concurrently to the third and to the fourth steps and when the plurality of channel coefficients representative of the communication channel ĥ₁ . . . ĥₖ are identified, the parameters of the indirect MUD filter 252 are computed.

When the parameters of the indirect MUD filter 252 are computed, the payload data b containing the information are estimated with the indirect MUD filter 252 using the data \tilde{r}^{pilot free}.

Concurrently to the last step, the plurality of channel coefficients representative of the communication channel ĥ₁ . . . ĥₖ are tracked using the second step and the received data with pilot free are computed by applying the third step and the fourth step.

In time variant channel conditions, the plurality of channel coefficients representative of the communication channel ĥ₁ . . . ĥhd k are tracked using the second step, the third step and the last step.

Now referring to FIG. 6, there is shown a receiver operating according to a mixed adaptation method based on a channel identification unit 12 and generating a training sequence of data at the receiver (no need to transmit the training data) used in order to adapt the parameters of the direct MUD filter 251.

According to a first step, the parameters of the direct MUD filter 251 and the parameters of the channel identification unit 12 are initialized.

According to a second step, the training control sequence p^{train} is transmitted through the channel in order to perform the training sequence of the channel identification unit 12 for all channels defined by the K users. Concurrently, the payload data b containing the information sent by the K users are transmitted. The training control sequence p^{train} is known by the receiver and is used in order to identify the parameters of the channel model H(●). A channel identification method such as the Correlator, Maximum Likelihood, etc. and/or following an adaptation algorithm such as the LMS, RLS, Kalman filter, Backpropagation Neural Network, etc. is used by the channel identification unit 12 in order to identify the parameters of the channel model H(●) (the plurality of channel coefficients representative of the communication channel ĥ₁ . . . ĥₖ).

According to a third step, when the parameters of the channel model H(●) are identified, a set of training data sequences b^{train} and training control sequence p^{train} are generated locally at the receiver. The set of training data sequences b^{train} is used in order to generate the receive data sequence r^{data} using the channel data modeling unit 610 while the training control sequence p^{train} is used in order to generate the regenerated control sequence r^{pilot} using the channel control modeling unit 410.

According to a fourth step, a summation of r^{data} with r^{pilot} produces the receive signal r^{train} using adding unit 620.

According to a fifth step, the switches K¹⁻¹ and K¹⁻² are both in position A in order to perform the training sequence for all channels defined by the K users.

According to a sixth step, the generated set of training data sequences b^{train} and the receive signal r^{train} are used in order to adapt the parameters of the direct MUD filter 251 following an adaptation algorithm such as an LMS, RLS, Neural Network Backpropagation, etc.

According to a seventh step, when the parameters of the direct MUD filter 251 are adapted, the switches K¹⁻¹ and K¹⁻² are both set in position B. The payload data b containing the information are estimated with the direct MUD filter 251 using the data \tilde{r}.

Periodically, the switches K¹⁻¹ and K¹⁻² in position A and B are changed alternatively to repeat steps 2 to 7 in order to adapt the parameters of the direct MUD filter 251 in variant channel H(●) conditions.

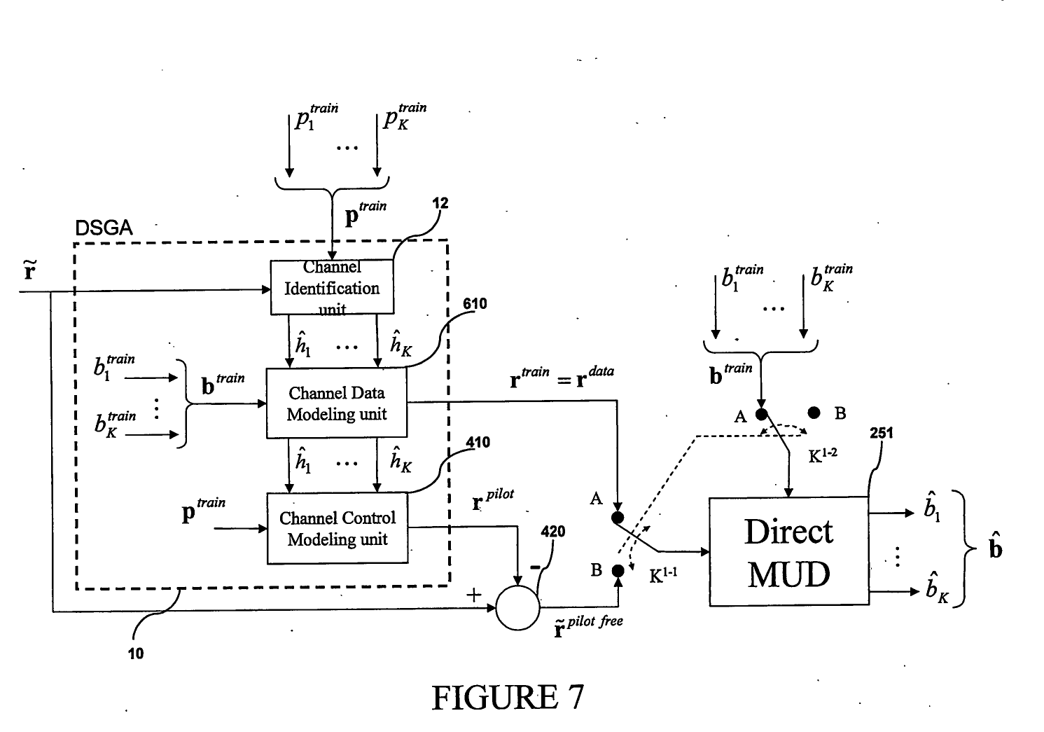

Now referring to FIG. 7, there is shown a receiver operating according to a mixed adaptation method, based on the same scheme as is described in FIG. 6, with a control (pilot) free signal added.

According to a first step, the parameters of the direct MUD filter 251 and the parameters of the channel identification unit 12 are initialized.

According to a second step, the training control sequence p^{train} is transmitted through the channel in order to obtain the training sequence of the channel identification unit 12 for all channels defined by the K users. Concurrently, the payload data b, not shown, containing the information sent by the K users are transmitted. The training control sequence p^{train} is known by the receiver and is used in order to identify the parameters of the channel model H(●). A channel identification method such as the Correlator, Maximum Likelihood, etc. and/or following an adaptation algorithm such as the LMS, RLS, Kalman filter, Backpropagation Neural Network, etc. may be used by the channel identification unit 12.

According to a third step, when all parameters of the channel data modeling unit 610 and the channel control modeling unit 410 are identified, a set of training data sequence b^{train} and training control sequence p^{train} are generated locally at the receiver. The set of training data sequence b^{train} is used in order to generate the receive data sequence r^{data} using the channel data modeling unit 610 and the training control sequence p^{train} is used in order to generate the regenerated control sequence r^{pilot} using the Channel control modeling unit 410.

According to a fourth step, the switches K¹⁻¹ and K¹⁻² are both in position A in order to perform the training sequence for all channels defined by the K users.

According to a fifth step, the generated set of training data sequence b^{train} and the control sequence r^{train} are used to adapt the parameters of the direct MUD filter 251 following an adaptation algorithm such as an LMS, RLS, Neural Network Backpropagation, etc.

According to a sixth step, performed concurrently to the third step, a set of data sequence r^{pilot} is produced by the channel data modeling unit 610.

According to a seventh step, in control (pilot) free conditions, the effect of the control (pilot) data interferes with the payload data and must therefore be cancelled. The cancellation is performed by a subtraction of the received data \tilde{r} by the r^{pilot} using the control signal cancellation unit 420. The control signal cancellation unit 420 provides the new received data \tilde{r}^{pilot free}.

When the parameters of the direct MUD filter 251 are adapted, and according to the eighth step, the switches K¹⁻¹ and K¹⁻² are both in position B. The payload data b containing the information are estimated with the direct MUD filter 251 using the data \tilde{r}^{pilot free}.

According to a ninth step, concurrently performed to the seventh step, the parameters of the channel identification unit 12 are tracked using the second step and the receive data with pilot free are used in the sixth step and the seventh step.

According to a tenth step, the switches, in position A and B, are changed alternatively to repeat the steps 2 to 9 in order to adapt the parameters of the direct MUD filter 251 in variant channel H(●) conditions.

In addition, a blind adaptation procedure described above may be applied to these adaptation methods in order to increase the bandwidth efficiency.

While illustrated in the block diagrams as groups of discrete components communicating with each other via distinct data signal connections, it will be understood by those skilled in the art that the preferred embodiments are provided by a combination of hardware and software components, with some components being implemented by a given function or operation of a hardware or software system, and many of the data paths illustrated being implemented by data communication within a computer application or operating system. The structure illustrated is thus provided for efficiency of teaching the present preferred embodiment.

It should be noted that the present invention can be carried out as a method, can be embodied in a system, a computer readable medium or an electrical or electromagnetical signal.

The embodiment(s) of the invention described above is(are) intended to be exemplary only. The scope of the invention is therefore intended to be limited solely by the scope of the appended claims.

We claim:

1. An apparatus for providing a regenerated data sequence, said apparatus comprising:
a channel identification unit receiving, from a communication channel, a transmitted signal (\tilde{r}) and a training control sequence (p^{train}) to provide a plurality of channel coefficients representative of said communication channel (ĥ₁ . . . ĥₖ); and
a channel modeling unit filtering said plurality of channel coefficients representative of said communication channel (ĥ₁ . . . ĥₖ) with a known training data sequence, (X) to provide said regenerated data sequence (Y).

2. The apparatus as claimed in claim 1, wherein said training sequence (X) comprises said training control sequence (p^{train}), further wherein said regenerated data sequence (Y) comprises a regenerated control sequence (r^{pilot}), further wherein said channel modeling unit comprises a channel control modeling unit filtering said plurality of channel coefficients representative of said communication channel (ĥ₁ . . . ĥₖ) with said training control sequence (p^{train}) to provide said regenerated control sequence (r^{pilot}).

3. The apparatus as claimed in claim 2, further comprising a control signal cancellation unit, subtracting said regenerated control sequence (r^{pilot}) from said transmitted signal (\tilde{r}) to provide a control sequence free (\tilde{r}^{pilot free}) of said control sequence.

4. The apparatus as claimed in claim 1, wherein said training sequence (X) comprises a training data sequence (b^{train}), further wherein said regenerated data sequence (Y) comprises a regenerated training sequence (r^{train}), further wherein said channel modeling unit comprises a channel data modeling unit filtering said plurality of channel coefficients representative of said communication channel (ĥ₁ . . . ĥₖ) with said training data sequence (b^{train}) to provide said regenerated training sequence (r^{train}).

5. The apparatus as claimed in claim 4, wherein said channel modeling unit further comprises a channel control modeling unit filtering said plurality of channel coefficients representative of said communication channel (ĥ₁ . . . ĥₖ) with said training control sequence (p^{train}) to provide a regenerated control sequence (r^{pilot}).

6. An direct adaptation receiver for providing an estimated payload data sequence (\hat{b}), said receiver comprising:
an apparatus for generating a regenerated data sequence free of said control sequence comprising:
a channel identification unit receiving, from a communication channel, a transmitted signal (\tilde{r}) and a training control sequence (p^{train}) to provide a plurality of channel coefficients representative of said communication channel (ĥ₁ . . . ĥₖ); and
a channel modeling unit filtering said plurality of channel coefficients representative of said communication channel (ĥ₁ . . . ĥₖ) with said training control sequence (p^{train}) to provide regenerated control sequence (r^{pilot});
a control signal cancellation unit, subtracting said regenerated control sequence (r^{pilot}) from said transmitted signal (\tilde{r}) to provide said control sequence free (\tilde{r}^{pilot free}) of said control sequence; and
a filtering unit receiving said regenerated data sequence free of said control sequence and further selectively receiving a training data sequence (b^{train}) to provide said estimated payload data sequence (\hat{b}); and
wherein said filtering unit is adapted in accordance with said training data sequence (b^{train}).

7. A method apparatus for providing a regenerated data sequence, said method comprising:
receiving, from a communication channel, a transmitted signal (\tilde{r}) and a training control sequence (p^{train}) to provide a plurality of channel coefficients representative of said communication channel (ĥ₁ . . . ĥₖ); and
filtering said plurality of channel coefficients representative of said communication channel (ĥ₁ . . . ĥₖ) with a known training data sequence (X) to provide said regenerated data sequence (Y).

8. The method as claimed in claim 7, wherein said training sequence (X) comprises said training control sequence (p^{train}), further wherein said regenerated data sequence (Y) comprises a regenerated control sequence (r^{pilot}), further comprising filtering said plurality of channel coefficients representative of said communication channel (ĥ₁ . . . ĥₖ) with said training control sequence (p^{train}) to provide said regenerated control sequence (r^{pilot}).

9. The method as claimed in claim 8, further comprising subtracting said regenerated control sequence (r^{pilot}) from said transmitted signal (\tilde{r}) to provide a control sequence free (\tilde{r}^{pilot free}) of said control sequence.

10. The method as claimed in claim 7, wherein said training sequence (X) comprises a training data sequence (b^{train}), further wherein said regenerated data sequence (Y) comprises a regenerated training sequence (r^{train}), further comprising filtering said plurality of channel coefficients representative of said communication channel (ĥ₁ . . . ĥₖ) with said training data sequence (b^{train}) to provide said regenerated training sequence (r^{train}).

11. The method as claimed in claim 10, further comprising filtering said plurality of channel coefficients representative of said communication channel (ĥ₁ . . . ĥₖ) with said training control sequence (p^{train}) to provide a regenerated control sequence (r^{pilot}).

12. An adaptive method for optimizing the parameters of a filter at a receiver, the method comprises:
using first and second data sequences transmitted through a same communication channel, wherein said first data sequence includes as payload data and said second data sequence includes as training data;
using said training data to adapt the filter parameters at the receiver;
wherein said filter parameters are adapted in presence of varying channels that are received at the receiver at the same time as said data sequences are transmitted.
